(19) United States
(12) Patent Application Publication
(10) Pub. No.: US 2023/0331927 A1
(43) Pub. Date: Oct. 19, 2023

(54) POLYMETALLOXANE-CONTAINING COMPOSITION, CURED BODY, MEMBER, ELECTRONIC COMPONENT, AND FIBER

(71) Applicant: Toray Industries, Inc., Tokyo (JP)

(72) Inventors: Yohei Konoshima, Otsu-shi, Shiga (JP); Jun Oura, Otsu-shi, Shiga (JP); Mitsuhito Suwa, Otsu-shi, Shiga (JP)

(21) Appl. No.: 18/043,348

(22) PCT Filed: Aug. 23, 2021
(86) PCT No.: PCT/JP2021/030753

§ 371 Date: Feb. 28, 2023

(30) Foreign Application Priority Data
Sep. 11, 2020 (JP) 2020-152698

(51) Int. Cl. C08G 79/14; C08G 79/10; C01B 33/26; D01F 9/00

(52) U.S. Cl. CPC C08G 79/14; C08G 79/10; C01B 33/26; D01F 9/00; H01L 21/31144

(57) ABSTRACT

A composition including: (A) a polymetalloxane having a repeating structure of a metal atom selected from the group consisting of Al, Sc, Ti, V, Cr, Mn, Fe, Co, Ni, Cu, Zn, Ga, Ge, Y, Zr, Nb, Mo, In, Sn, Sb, Hf, Ta, W, and Bi and an oxygen atom; and (B) an aromatic polyfunctional amine compound.

### TECHNICAL FIELD

This disclosure relates to a polymetalloxane-containing composition, a cured product, and a method of producing the same, and to a member, an electronic component, and a fiber.

### BACKGROUND

At present, communications devices such as smartphones and tablets are more and more widely used, accordingly encouraging the development of new-generation integrated circuits (ICs) having a higher performance and a larger functionality. With a semiconductor memory in particular, a memory cell array made three-dimensionally structured is promising for a higher degree of integration and a lower cost. That which is desired for a production process for such a semiconductor memory is a technology of processing an inorganic solid composed of a single or a plurality of layers into a pattern having a high aspect ratio.

A known method of processing an inorganic solid into a pattern is a method in which a patterned mask is formed on an inorganic solid to be processed, and then, the inorganic solid is processed into a pattern by dry etching using the mask. When the inorganic solid is processed by dry etching into a pattern having a high aspect ratio, the mask used to form the pattern is exposed to etching gas for a long time. Accordingly, the mask preferably has a high etching resistance. Such a mask to be suitably used is a cured film composed of a metal oxide. A cured film composed of a metal oxide has properties such as a high heat resistance, a high transparency, a high refractive index, and the like, and is promisingly expected to have properties useful for various applications.

As a method of forming such a cured film composed of a metal oxide, a method of curing a composition containing a polymetalloxane is disclosed (see, for example, WO 2017/090512 A1 and WO 2019/031250 A1). A polymetalloxane can be cured by heating, and thus, can form a homogeneous cured film in a simple manner.

A mask to be used to form a pattern having a high aspect ratio by dry etching involves having a high etching resistance and besides a heat resistance and a thickness that make it possible to withstand high-temperature baking. For example, when a cured product having a thickness of 0.5 μm or more is baked at 400° C. or more using such a technology as described in WO 2017/090512 A1 and WO 2019/031250 A1, the cured product sometimes cracks, making it difficult to achieve both heat resistance and larger film thickness.

It could therefore be helpful to provide a composition that makes it possible to form a cured product that does not crack, has a large film thickness, and has a high film density even after undergoing high-temperature baking.

### SUMMARY

We discovered that allowing a composition containing a polymetalloxane to further contain (B) an aromatic polyfunctional amine compound is extremely effective to address the above-mentioned issues.

We thus provide a composition containing: (A) a polymetalloxane having a repeating structure of a metal atom selected from the group consisting of Al, Sc, Ti, V, Cr, Mn, Fe, Co, Ni, Cu, Zn, Ga, Ge, Y, Zr, Nb, Mo, In, Sn, Sb, Hf, Ta, W, and Bi and an oxygen atom; and (B) an aromatic polyfunctional amine compound.

Our composition makes it possible to obtain a cured product that does not crack, has a large film thickness, and has a high density even after undergoing high-temperature baking.

### DETAILED DESCRIPTION

Our resin composition contains: (A) a polymetalloxane (“(A) the polymetalloxane”) having a repeating structure of a metal atom selected from the group consisting of Al, Sc, Ti, V, Cr, Mn, Fe, Co, Ni, Cu, Zn, Ga, Ge, Y, Zr, Nb, Mo, In, Sn, Sb, Hf, Ta, W, and Bi and an oxygen atom; and (B) an aromatic polyfunctional amine compound.

### (A) Polymetalloxane

A polymetalloxane is a polymer having a repeating structure of a metal atom and an oxygen atom and having a metal-oxygen-metal bond as a main chain. The metal atom contained in (A) the polymetalloxane is selected from the group consisting of Al, Sc, Ti, V, Cr, Mn, Fe, Co, Ni, Cu, Zn, Ga, Ge, Y, Zr, Nb, Mo, In, Sn, Sb, Hf, Ta, W, and Bi. Containing such a metal atom makes it possible to obtain a metal oxide having a high heat resistance. The metal atom is preferably a metal atom selected from the group consisting of Al, Ti, Y, Zr, Nb, and Sn. Containing such a metal atom allows a metal alkoxide used as the below-mentioned synthetic raw material of a polymetalloxane to be present stably, thus making it easy to obtain a polymetalloxane having a high molecular weight. The metal atom is more preferably Al, Ti, or Zr, still more preferably Al or Zr. Containing such a metal atom makes it possible to enhance the density of a cured product formed by curing a composition, and makes it possible to enhance the etching resistance.

The lower limit of the weight-average molecular weight of (A) the polymetalloxane is preferably 10,000 or more, more preferably 50,000 or more, still more preferably 200,000 or more. In addition, the upper limit is preferably 2,000,000 or less, more preferably 1,500,000 or less, still more preferably 1,000,000 or less. Having the lower limit of the weight-average molecular weight of the polymetalloxane within the above-mentioned range allows the factor of shrinkage of the polymer in the baking step to be decreased, thus enhancing the crack resistance. In addition, that the weight-average molecular weight of the polymetalloxane is a value equal to or less than the above-mentioned upper limit makes it possible to enhance the solubility of the polymetalloxane in a solvent, and makes it possible to apply the polymetalloxane to a base plate without nonuniformity, thus making it possible to obtain a metalloxane cured product having a high in-plane uniformity.

The weight-average molecular weight means a value measured by gel permeation chromatography (GPC) in terms of polystyrene. The weight-average molecular weight of the polymetalloxane can be determined by the following method. A polymetalloxane is dissolved at a concentration of 0.2 wt % in an eluent to obtain a sample solution. Subsequently, the sample solution is injected into a column packed with a porous gel and an eluent, and measured by gel permeation chromatography (GPC). The column eluate is detected by a differential refractive index detector, and the elution time is analyzed to determine the weight-average molecular weight. An eluent to be selected is that which can dissolve a polymetalloxane at a concentration of 0.2 wt %. If a polymetalloxane is dissolved in an N-methyl-2-pyrrolidone solution of 0.02 mol/dm³ lithium chloride, this eluent is used.

(A) the polymetalloxane is not limited to any particular repeating structural unit, and preferably has a structural unit represented by the following general formula (2).

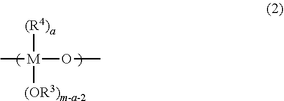

R³ is a hydrogen atom or a C₁₋₁₂ alkyl group. R⁴ is a hydroxy group, a C₁₋₁₂ alkyl group, a C₅₋₁₂ alicyclic alkyl group, a C₁₋₁₂ alkoxy group, a C₆₋₁₂ aryl group, a C₆₋₃₀ phenoxy group, a C₁₀₋₃₀ naphthoxy group, a C₇₋₁₃ aralkyl group, a (R⁵₃SiO—) group, a (R⁶R⁷NO—) group, or a group having a metalloxane bond. A plurality of R³s and R⁴s existing in the polymetalloxane may be the same or different.

R⁵ is a group selected from the group consisting of a hydroxy group, a C₁₋₁₂ alkyl group, a C₅₋₁₂ alicyclic alkyl group, a C₁₋₁₂ alkoxy group, a C₆₋₁₂ aryl group, a C₇₋₁₃ aralkyl group, and a group having a siloxane bond. A plurality of R⁵s may be the same or different.

R⁶ and R⁷ are independently a hydrogen atom, a C₁₋₁₂ alkyl group, a C₅₋₁₂ alicyclic alkyl group, a C₆₋₁₂ aryl group, a C₇₋₁₃ aralkyl group, or a C₁₋₁₂ acyl group. R⁶ and R⁷ may be linked via a carbon-carbon saturated bond or a carbon-carbon unsaturated bond to form a ring structure.

M represents a metal atom selected from the group consisting of Al, Sc, Ti, V, Cr, Mn, Fe, Co, Ni, Cu, Zn, Ga, Ge, Y, Zr, Nb, Mo, In, Sn, Sb, Hf, Ta, W, and Bi.

m is an integer that represents a valence of a metal atom M, and a is an integer of 1 to (m-2).

Examples of C₁₋₁₂ alkyl groups include a methyl group, an ethyl group, a propyl group, an isopropyl group, a butyl group, an isobutyl group, an s-butyl group, a t-butyl group, a pentyl group, a hexyl group, a heptyl group, an octyl group, a 2-ethylhexyl group, a nonyl group, a decyl group, an undecyl group, a dodecyl group and the like.

Examples of C₅₋₁₂ alicyclic alkyl groups include a cyclopentyl group, a cyclohexyl group, a cycloheptyl group, a cyclooctyl group, a cyclononyl group, a cyclodecyl group and the like.

Examples of C₁₋₁₂ alkoxy groups include a methoxy group, an ethoxy group, a propoxy group, an isopropoxy group, a butoxy group, an isobutoxy group, an s-butoxy group, a t-butoxy group, a pentoxy group, a hexyloxy group, a heptoxy group, an octoxy group, a 2-ethylhexyloxy group, a nonyl group, a desiloxy group and the like.

Examples of C₆₋₁₂ aryl groups include a phenyl group, a phenoxy group, a naphthyl group and the like.

Examples of C₇₋₁₃ aralkyl groups include a benzyl group, a phenethyl group, a phenylpropyl group, a phenylethyl group, a phenylbutyl group, a phenylpentyl group, a phenylhexyl group, a phenylpentyl group and the like.

Examples of (R⁵₃SiO—) groups include a trihydroxysiloxy group, a trimethylsiloxy group, a triethylsiloxy group, a tripropylsiloxy group, a triisopropylsiloxy group, a tributylsiloxy group, a triisobutylsiloxy group, a tri-s-butylsiloxy group, a tri-t-butylsiloxy group, a tricyclohexylsiloxy group, a trim ethoxy siloxy group, a triethoxysiloxy group, a tripropoxysiloxy group, a triisopropoxysiloxy group, a tributoxysiloxy group, a triphenylsiloxy group, a hydroxydiphenylsiloxy group, a methyldiphenylsiloxy group, an ethyldiphenylsiloxy group, a propyldiphenylsiloxy group, a dihydroxy(phenyl)siloxy group, a dimethyl(phenyl)siloxy group, a diethyl(phenyl)siloxy group, a dipropyl(phenyl)siloxy group, a trinaphthylsiloxy group, a hydroxydinaphthylsiloxy group, a methyldinaphthylsiloxy group, an ethyldinaphthylsiloxy group, a propyldinaphthylsiloxy group, a dihydroxy(naphthyl)siloxy group, a dimethyl(naphthyl)siloxy group, a diethyl(naphthyl)siloxy group, a dipropyl(naphthyl)siloxy group and the like.

Examples of (R⁶R⁷NO—) groups include a diethylaminooxy group, a dibenzylaminooxy group, a 2-azaadamantanyloxy group; a formamide group, a formanilide group, an acetamide group, an acetanilide group, a trifluoroacetamide group, a 2,2,2,2-trifluoroacetanilide group, a benzamide group, a benzanilide group, a pyrrolidone group, a piperidone group; an N-acetamidyloxy group, an N-octanamidyloxy group, an N-benzamidyloxy group, an N-benzoyl-N-phenyl aminooxy group, an N-naphthalene-1-carboxyamidyloxygroup, an N-salicylamidyloxy group, an α-(p-butoxyphenyl)-N-acetamidyloxy group, an N-succinimidyloxy group, an N-phthalimidyloxy group, an N-(4-nitrophthalimidyl)oxy group, an N-(5 -norbornene-2,3-dicarboxyimidyl)oxy group, an N-oxysulfosuccinimide sodium group, an N-(N′-hydroxypyromellitimidyl)oxy group, an N-(1,8-naphthalimidyl)oxy group, an N-(N′-hydroxy-1,2,3,4-cyclobutanetetracarboxylic acid diimidyl)oxy group and the like.

A group having a metalloxane bond refers to that which has an oxygen atom as R⁴, in which the oxygen atom mediates a direct bond with a metal atom M of another polymetalloxane chain.

A group having a siloxane bond refers to that which has an oxygen atom as R⁵, in which the oxygen atom mediates a direct bond with Si of another siloxane chain.

(A) the polymetalloxane having a repeating structural unit represented by general formula (2) makes it possible to form a cured product mainly composed of a resin containing, in a main chain, a metal atom having a high electron density. Accordingly, the density of a metal atom in the cured product can be increased, thus making it possible to easily achieve a high density. In addition, the cured product becomes a dielectric containing no free electron, thus making it possible to obtain a cured product having a high transparency and a high heat resistance.

(A) the polymetalloxane preferably contains a repeating structural unit in which at least one of the R⁴s in general formula (2) is an (R⁵₃SiO—) group, an (R⁶R⁷NO—) group, or a group having a metalloxane bond. (A) the polymetalloxane having the functional group makes it possible to enhance the stability of the polymetalloxane in a solution. Accordingly, it is possible to perform polymerization without precipitation during the below-mentioned synthesis of a polymetalloxane, thus making it possible to easily obtain a polymetalloxane having a weight-average molecular weight of 10,000 or more and 2,000,000 or less. In addition, it is also possible to inhibit a defect from being generated in the cured product by a change in the quality of the metalloxane in a solution, and thus to enhance the crack resistance.

From the viewpoint of crack resistance, (A) the polymetalloxane more preferably contains a repeating structural unit in which at least one of the R⁴s in general formula (2) is an (R⁵₃SiO—) group or a group having a metalloxane bond.

A method of synthesizing (A) the polymetalloxane is not subject to any particular limitation, and preferably includes a step in which a compound represented by general formula (3) and/or general formula (4) is hydrolyzed, if needed, and then partially condensed and polymerized. The partial condensation means not to condense all the M—OH units of the hydrolyzate, but to leave a part of the M—OH units in the resulting polymetalloxane. Under the below-mentioned general condensation conditions, it is general that the M—OH units partially remain. The amount of the remaining M—OH units is not subject to any limitation.

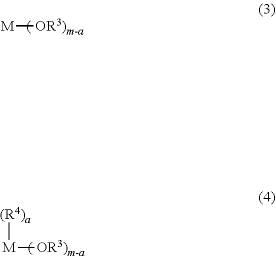

R³, R⁴, M, m, and a are as described above.

Examples of more specific methods of synthesizing a polymetalloxane include methods described in WO 2019/188834 and WO 2019/188835.

Examples of compounds represented by general formula (3) include, but are not limited particularly to, a metal alkoxide described in WO 2017/90512 and the like.

Examples of compounds represented by general formula (4) include, but are not limited particularly to, compounds exemplified as compounds represented by general formula (2) in the same literature, compounds exemplified as compounds represented by general formula (4) in WO 2019/188835 and the like.

If desired, a catalyst is added in the synthesis of a polymetalloxane. Examples of catalysts to be preferably used include, but are not limit particularly to, basic catalysts. Using a basic catalyst makes it possible to obtain a high-molecular-weight polymetalloxane in particular. Among basic catalysts, (B) the aromatic polyfunctional amine compound is more preferably used. Using (B) the aromatic polyfunctional amine compound makes it possible to obtain a cured product having an excellent crack resistance from a polymetalloxane composition.

### (B) Aromatic Polyfunctional Amine Compound

(B) the aromatic polyfunctional amine compound (“(B) the amine compound”) is an aromatic amine compound having two or more amine functional groups in one molecule.

Our composition contains (B) the amine compound, and hence, a nitrogen atom in (B) the amine compound forms a salt with a hydroxyl group contained in (A) the polymetalloxane, thus making it possible to relax the forming rate of a metalloxane bond in the baking step. This makes it possible to avoid stress concentration due to the shrinkage of a cured product during formation, and to enhance the crack resistance. In addition, having an aromatic moiety enhances the heat resistance of (B) the amine compound, and thus, contributes significantly to enhancing the crack resistance of a cured product during formation at a high temperature.

(B) the amine compound is preferably a compound having, in one molecule, 2 to 30 structures represented by general formula (1).

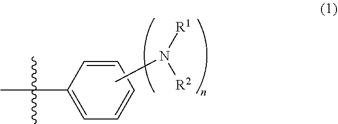

In general formula (1), R¹ and R² independently represent a hydrogen atom or a C₁₋₈ organic group. n is an integer of 1 to 3.

From the viewpoint of easiness of interaction with (A) the polymetalloxane, R¹ and R² preferably have a smaller steric hindrance, and thus, are preferably a hydrogen atom or a C₁₋₃ organic group, still more preferably a hydrogen atom.

Examples of C₁₋₈ organic groups to be used for R¹ and R² include an aromatic hydrocarbon group, an aliphatic hydrocarbon group, and the like. The aliphatic hydrocarbon group may be linear or branched, or may be partially or wholly cyclic. Examples of C₁₋₈ hydrocarbon groups include a methyl group, an ethyl group, a propyl group, an isopropyl group, a butyl group, an isobutyl group, a pentyl group, a cyclopentyl group, a hexyl group, a cyclohexyl group, a heptyl group, a cycloheptyl group, an octyl group, a cyclooctyl group and the like. Among these, a methyl group, an ethyl group, or a propyl group is preferable from the viewpoint of having a smaller steric hindrance and not impairing the interaction with (A) the polymetalloxane.

(B) the amine compound having two or more structures represented by general formula (1) undergoes a firmer interaction with (A) the polymetalloxane, resulting in enhancing the crack resistance of the cured product. In addition, (B) the amine compound having 30 or less structures represented by general formula (1) makes it possible to enhance the density of the cured product. The lower limit of the number of structures represented by general formula (1) in (B) the amine compound is preferably 3 or more. In addition, the upper limit is preferably 20 or less, more preferably 10 or less.

Specific examples of (B) the amine compound having, in one molecule, two structures represented by general formula (1) include benzidine, N,N,N′,N′-tetramethyl benzidine, 2,2′-dimethyl-4,4′-diphenyldiamine, 2,2′-dimethyl-3,4′-diphenyldiamine, 2,2′-dimethyl-3,3′-diphenyldiamine, 2,2′-dimethyl-N,N,N′,N′-tetramethyl-4,4′-diphenyldiamine, 2,2′-dimethyl-N,N,N′,N′-tetramethyl-3,4′-diphenyldiamine, 2,2′-dimethyl-N,N,N′,N′-tetramethyl-3,3′-diphenyldiamine, 4,4′-diaminobiphenyl ether, 3,4′-diaminobiphenyl ether, 3,3′-diaminobiphenyl ether, N,N,N′,N′-tetramethyl-4,4′-diaminobiphenyl ether, N,N,N′,N′-tetramethyl-3,4′-diaminobiphenyl ether, N,N,N′,N′-tetramethyl-3,3′-diaminobiphenyl ether, 4,4′-diaminobiphenylmethane, 3,4′-diaminobiphenylmethane, 3,3′-diaminobiphenylmethane, N,N,N′,N′-tetramethyl-4,4′-diaminobiphenylmethane, N,N,N′,N′-tetramethyl-3,4′-diaminobiphenylmethane, N,N,N′,N′-tetramethyl-3,3′-diaminobiphenylmethane, 2,2′-diaminobenzidine, 3,3′-diaminobenzidine, 2,2′-dimethoxy-4,4′-diaminobiphenyl, 3,3′-dimethoxy-4,4′-diaminobiphenyl and the like.

Specific examples of (B) the amine compound having, in one molecule, three structures represented by the general formula (1) include 1,3,5-tris(4-aminophenoxy)benzene, 1,3,5-tris(3-aminophenoxy)benzene, 1,3,5-tris(2-aminophenoxy)benzene, 1,3,5-tris(N,N,N′,N′-tetramethyl-4-aminophenoxy)benzene, 1,3,5-tris(N,N,N′,N′-tetramethyl-3-aminophenoxy)benzene, 1,3,5-tris(N,N,N′,N′-tetramethyl-2-aminophenoxy)benzene, 1,3,5-tris(4-aminophenyl)benzene, 1,3,5-tris(3-aminophenyl)benzene, 1,3,5-tris(2-aminophenyl)benzene, 1,3,5-tris(N,N,N′,N′-tetramethyl-4-aminophenyl)benzene, 1,3,5-tris(N,N,N′,N′-tetramethyl-3-aminophenyl)benzene, 1,3,5-tris(N,N,N′,N′-tetramethyl-2-aminophenyl)benzene, 1,3,5-tris(4-aminophenyl)triazine, 1,3,5-tris(3-aminophenyl)triazine, 1,3,5-tris(2-aminophenyl)triazine, 1,3,5-tris(N,N,N′,N′-tetramethyl-4-aminophenyl)triazine, 1,3,5-tris(N,N,N′,N′-tetramethyl-3-aminophenyl)triazine, 1,3,5-tris(N,N,N′,N′-tetramethyl- 2-aminophenyl)triazine, 4,4′,4″-triaminophenylamine, 3,3′,3″-triaminophenylamine, 2,2′,2″-triaminophenylamine, N,N,N′,N′-tetramethyl-4,4′,4″-triaminophenylamine, N,N,N′,N′-tetramethyl-3,3′,3″-triaminophenylamine, N,N,N′,N′-tetramethyl-2,2′,2″-triaminophenylamine, 2,4′,4″-methylidynetrianiline, 4,4′,4″-methylidynetrianiline, 1,3,5-tris[1-(4-aminophenyl)-1-methylethyl]benzene,(4-amino-3-methylphenyl)-bis-(4-aminophenyl)methane, 1,3,5-triazine-2,4,6(1H,3H,5H)-trione, 1,3,5-tris[(3-aminophenyl)methyl] and the like.

Specific examples of (B) the amine compound having, in one molecule, 4 or more and 30 or less structures represented by the general formula (1) include tetrakis(4-aminophenyl)methane, tetrakis(3-aminophenyl)methane, tetrakis(2-aminophenyl)methane, tetrakis(N,N,N′,N′-tetramethyl-4-aminophenyl)methane, tetrakis(N,N,N′,N′-tetramethyl-3-aminophenyl)methane, tetrakis(N,N,N′,N′-tetramethyl-2-aminophenyl)methane, 1,1,2,2-tetrakis(4-aminophenyl)ethane, 1,1,2,2-tetrakis(3-aminophenyl)ethane, 1,1,2,2-tetrakis(2-aminophenyl)ethane, 1,1,2,2-tetrakis(N,N,N′,N′-tetramethyl-4-aminophenyl)ethane, 1,1,2,2-tetrakis(N,N,N′,N′-tetramethyl-3-aminophenyl)ethane, 1,1,2,2-tetrakis(N,N,N′,N′-tetramethyl-2-aminophenyl)ethane, 1,3,5,7-tetrakis(4-aminophenyl)adamantane, 1,3,5,7-tetrakis(3-aminophenyl)adamantane, 1,3,5,7-tetrakis(2-aminophenyl)adamantane, 1,3,5,7-tetrakis(N,N,N′,N′-tetramethyl-4-aminophenyl)adamantane, 1,3,5,7-tetrakis(N,N,N′,N′-tetramethyl-3-aminophenyl)adamantane, 1,3,5,7-tetrakis(N,N,N′,N′-tetramethyl-2-aminophenyl)adamantane, N,N,N′,N′-tetrakis(4-aminophenyl)-1,4-phenylenediamine, N,N,N′,N′-tetrakis(3-aminophenyl)-1,4-phenylenediamine, N,N,N′,N′-tetrakis(2-aminophenyl)-1,4-phenylenediamine, [1,1′-biphenyl]-4,4′ diamine,N′,N′,N′,N′-tetrakis(4-aminophenyl), [1,1′-biphenyl]-4,4′ diamine,N′,N′,N′,N′-tetrakis(3-aminophenyl), [1,1′-biphenyl]-4,4′ diamine,N′,N′,N′,N′-tetrakis(2-aminophenyl) and the like.

The amount of (B) the amine compound is preferably 20 to 150 parts by mass with respect to 100 parts by mass of (A) the polymetalloxane. Containing (B) the amine compound in an amount of 20 parts by mass or more enables the cured product to have a more enhanced crack resistance. The amount of (B) the amine compound is more preferably 21 parts by mass or more, still more preferably 25 parts by mass or more. On the other hand, containing (B) the amine compound in an amount of 150 parts by mass or less increases the ratio of (A) the polymetalloxane in the cured product, thus enabling the cured product to have an enhanced density. The amount of (B) the amine compound is more preferably 120 parts by mass or less, still more preferably 100 parts by mass or less.

### Solvent

Our composition may contain an organic solvent. Allowing the composition to contain an organic solvent makes it possible to adjust the composition to an arbitrary viscosity. This makes the coating film properties of the composition good.

As the organic solvent, an organic solvent in a polymetalloxane solution obtained in the production of a polymetalloxane may be used directly, or another organic solvent may be added.

The organic solvent contained in the composition is preferably, but not limited particularly to, the same solvent as used in the synthesis of the polymetalloxane. The organic solvent is still more preferably an aprotic polar solvent. Using an aprotic polar solvent enhances the stability of the polymetalloxane. This enables the composition to undergo a smaller increase in viscosity during a long-time storage and have an excellent storage stability.

Specific examples of aprotic polar solvents include acetone, tetrahydrofuran, ethyl acetate, dimethoxyethane, N,N-dimethylformamide, dimethyl acetamide, dipropylene glycol dimethyl ether, tetramethylurea, diethylene glycol ethylmethyl ether, dimethylsulfoxide, N-methylpyrrolidone, γ-butyrolactone, 1,3-dimethyl-2-imidazolidinone, propylene carbonate, N,N′-dimethylpropyleneurea, N,N-dimethylisobutylamide and the like.

The solid concentration of the composition is preferably 1 mass % or more and 50 mass % or less, still more preferably 2 mass % or more and 40 mass % or less. The composition having a solid concentration within the range enables a coating film in the below-mentioned coating step to have a favorable film thickness uniformity. The solid concentration of the composition can be determined by weighing 1.0 g of the composition in an aluminum cup, heating the composition at 250° C. for 30 minutes using a hot plate to evaporate the liquid component, and weighing the solid component remaining in the aluminum cup after heating.

The viscosity at 25° C. of the composition containing a polymetalloxane is preferably 1 mPa·s or more and 1000 mPa·s or less, more preferably 1 mPa·s or more and 500 mPa·s or less, still more preferably 1 mPa·s or more and 200 mPa·s or less. The composition having a viscosity within the range enables the coating film in the below-mentioned coating step to have a favorable film thickness uniformity. The viscosity of the composition is determined by measuring that of the composition having a temperature of 25° C., using an E type viscometer at any rotational speed.

### Other Components

Our composition may contain another component. Examples of the another component include inorganic particles, a surfactant, a silane coupling agent, a cross-linking agent, a cross-linking accelerator and the like.

### Cured Product

Curing the composition by heating makes it possible to obtain a cured product. In a cured product that is a cured film, the composition is applied to a base plate, and then cured by heating to afford a cured film. The cured product thus obtained results in a cured product mainly composed of a resin having, in a main chain, a metal atom having a high electron density, so that the concentration of the metal atom in the cured product can be increased, thus making it possible to easily obtain a cured product having a high density. In addition, the cured product obtained becomes a dielectric containing no free electrons, and thus, has a high heat resistance.

Examples of a base plate for forming a cured product include, but are not particularly limited to, a silicon wafer, a sapphire wafer, glass, an optical film and the like. Example of glasses include alkali glass, alkali-free glass, thermally tempered glass, chemically tempered glass or the like. Examples of optical films include a film made of an acrylic resin, a polyester resin, a polycarbonate, a polyarylate, a polyether sulfone, a polypropylene, a polyethylene, a polyimide, or a cycloolefin polymer.

An inorganic solid may be formed on the base plate. The inorganic solid is a generic term for solids that are other than organic compounds and are constituted by a non-metal substance. Without any particular limitation, the inorganic solid is preferably constituted by one or more materials selected from the group consisting of silicon oxide (SiO₂), silicon nitride (Si₃N₄), aluminum oxide (Al₂O₃), titanium oxide (TiO₂), zirconium oxide (ZrO₂), silicon carbide (SiC), gallium nitride (GaN), gallium arsenide (GaAs), indium phosphide (InP), aluminum nitride (AlN), tantalum nitride (TaN), lithium tantalate (LiTaO₃), boron nitride (BN), titanium nitride (TiN), barium titanate (BaTiO₃), indium oxide (InO₃), tin oxide (SnO₂), zinc sulfide (ZnS), zinc oxide (ZnO), tungsten oxide (WO₃), molybdenum oxide (MoO₃), and silicon (Si), still more preferably constituted by one or more materials selected from the group consisting of SiO₂, Si₃N₄, Al₂O₃, TiO₂, and ZrO₂. The inorganic solid may be a composite composed of a plurality of inorganic solids.

As a method of coating a base plate with a composition, any known method can be used. Examples of an apparatus used for coating include full-surface coating apparatuses such as for spin coating, dip coating, curtain flow coating, spray coating, or slit coating, or printing apparatus such as screen printing, roll coating, micro gravure coating, or ink jet.

After the base plate is coated with the composition, the coating may be heated (prebaked) using a heating device such as a hot plate or an oven. The coating film prebaked is referred to as a prebaked film. Prebaking is preferably performed at 50° C. or more and 150° C. or less for 30 seconds to 30 minutes. Prebaking makes it possible to obtain a cured product having a film thickness uniformity. The film thickness after prebaking is preferably 0.1 μm or more and 15 μm or less.

A baking step is performed in which the coating film or the prebaked film is heated at 100° C. or more and 1000° C. or less, preferably 200° C. or more and 800° C. or less, more preferably 400° C. or more and 800° C. or less, for 30 seconds to 10 hours using a heating device such as a hot plate or an oven. Thus, a cured film containing a polymetalloxane can be obtained. Bringing the heating temperature to a value equal to or more than the lower limit allows the curing of the polymetalloxane to progress, and increases the density of the cured film. Bringing the heating temperature to a value equal to or less than the upper limit makes it possible to inhibit the heating from damaging the base plate, the inorganic solid, and the peripheral members.

The thickness of the cured film is preferably 0.1 to 15 μm, more preferably 0.2 to 10 μm. The cured film having a thickness equal to or more than the lower limit makes it possible that, when an inorganic solid is etched using the below-mentioned pattern of a cured film as a mask, the inorganic solid pattern formed is in the shape of a pattern having an excellent straightness in the depth direction. The cured film having a thickness equal to or less than the upper limit makes it possible to inhibit a stress from being applied to the inorganic solid and the base plate.

The cured product preferably has a density of 1.50 g/cm³ or more and 5.00 g/cm³ or less, more preferably 1.85 g/cm³ or more and 4.00 g/cm³ or less. Allowing the cured product to have a density equal to or more than the lower limit enhances the mechanical properties of the below-mentioned pattern of a cured product. This makes it possible that, when an inorganic solid is patterned by etching using the pattern of the cured product as a mask, the pattern of the cured product is hard to damage by the etching.

The density of the cured product can be measured by Rutherford backscattering spectroscopy (RBS). A measurement can be made by irradiating the cured product with an ion beam (H⁺ or He⁺⁺), and measuring the energy and intensity of ions scattered backward by Rutherford scattering.

A cured product includes: a metal atom selected from the group consisting of Al, Sc, Ti, V, Cr, Mn, Fe, Co, Ni, Cu, Zn, Ga, Ge, Y, Zr, Nb, Mo, In, Sn, Sb, Hf, Ta, W, and Bi; an oxygen atom; a carbon atom; and a nitrogen atom; wherein the cured product contains an aromatic polyfunctional amine compound having, in one molecule, 2 to 30 structures represented by general formula (1); and wherein a ratio of the carbon atom to the total amount of substance of the metal atom is 1.0 to 25.0 in a heated product formed by heating the cured product at 700° C. under a nitrogen atmosphere for 1 hour.

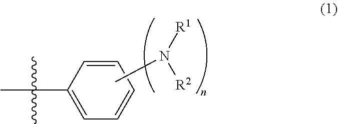

In general formula (1), R¹ and R² independently represent a hydrogen atom or a C₁₋₈ organic group. n is an integer of 1 to 3.

A ratio of the carbon atom to the total amount of substance of the metal atom is 1.0 to 25.0 in a heated product formed by heating at 700° C. under a nitrogen atmosphere for 1 hour. Thus, a cured product having a high density can be obtained. Having the carbon atom at a ratio of less than 1.0 causes a gap to be generated in the cured product, decreasing the density of the cured product. In addition, having the carbon atom at a ratio of more than 25.0 causes the ratio of the carbon atom in the cured product to increase, and causes the carbon atom to have a low density, thus decreasing the density of the cured product.

The atomic ratios of the cured product can be measured by Rutherford backscattering spectroscopy (RBS). The ratios of the atoms constituting the cured product can be calculated by irradiating the cured product with an ion beam (H⁺ or He⁺⁺), measuring the kinetic energy of ions scattered backward by Rutherford scattering, and measuring the mass number of an atom allowed to collide.

### Applications

### Applications as Masks for Inorganic Solid Etching

A cured product obtained from the composition is mainly composed of a polymetalloxane containing, in a main chain, a metal atom having a low reactivity with etching gas or an etchant during patterning an inorganic solid by etching, and thus, has a high etching resistance. Accordingly, a cured product can be utilized as a mask for patterning an inorganic solid by etching.

Examples of such a method of utilization include a method of producing an inorganic solid pattern, in which the method includes the steps of: coating an inorganic solid with the composition; heating a coating film from the coating step at 100° C. or more and 1000° C. or less to obtain a cured film; patterning the cured film to form a cured film pattern; and patterning the inorganic solid by etching using the cured film pattern as a mask.

The details of the step of forming a cured film in this method are as already described. The inorganic solid preferably includes one or more materials selected from the group consisting of SiO₂, Si₃N₄, Al₂O₃, TiO₂, and ZrO₂. In addition, the inorganic solid is preferably a laminate composed of a plurality of inorganic solid layers.

Examples of a preferable method of patterning a cured film to form a cured film pattern include, but are not limited particularly to, a method in which, on a cured film, a photoresist pattern is formed, or a hard mask pattern composed of a compound selected from the group consisting of SiO₂, Si₃N₄, and carbon or a composite compound thereof is formed, and the photoresist pattern or the hard mask pattern is used as a mask to etch the cured film. As a method of etching the cured film, a dry etching method or a wet etching method can be used.

The cured film is preferably dry-etched using a reactive ion etching apparatus (RiE apparatus) with a process gas such as methane trifluoride (CHF₃), methane tetrafluoride (CF₄), Cl₂ (chlorine), BCl₃ (boron trichloride), CCl₃ (carbon tetrachloride), oxygen, or a gas mixture thereof. The cured film is preferably wet-etched using that which is obtained by diluting hydrofluoric acid (HF), nitric acid (HNO₃), ammonium fluoride (NH₄F), phosphoric acid (H₃PO₄), or a mixture thereof with water and/or acetic acid (CH₃COOH).

A method of patterning an inorganic solid using, as a mask, a pattern of a cured film obtained as above-mentioned is preferably a dry etching method or a wet etching method.

The inorganic solid is preferably dry-etched using a reactive ion etching apparatus (RiE apparatus) with a process gas such as SF₆ (sulfur hexafluoride), NF₃ (nitrogen trifluoride), CF₄ (carbon tetrafluoride), C₂F₆ (ethane hexafluoride), C₃F₂ (propane octafluoride), C₄F₆ (hexafluoro-1,3-butadiene), CHF₃ (trifluoro methane), CH₂F₂ (difluoro methane), COF₂ (carbonyl fluoride), oxygen, or a gas mixture thereof.

The inorganic solid is preferably wet-etched using that which is obtained by diluting hydrofluoric acid (HF), nitric acid (HNO₃), ammonium fluoride (NH₄F), phosphoric acid (H₃PO₄), or a mixture thereof with water and/or acetic acid (CH₃COOH).

### Applications as Inorganic Solid Patterns

An inorganic solid pattern obtained as above-mentioned can be utilized as a semiconductor memory. The inorganic solid pattern is suitable particularly for a NAND flash memory that includes an inorganic solid pattern having a high aspect ratio.

### Applications as Electronic Components

Our cured product has an excellent refractive index and insulating properties, and thus, is suitably used for a member of an electronic component such as a solid image pickup device or a display. The member refers to a part included in an electronic component. Examples of members for solid image pickup devices include condensing lenses, light guides for connecting a condensing lens and a photosensor unit, antireflection films, and the like. Examples of members for displays include index matching materials, planarizing materials, insulation protecting materials and the like.

### Applications as Fibers

Our composition can be spun to form a fiber. Baking a fiber thus obtained makes it possible to obtain a metal oxide fiber.

A metal oxide fiber has properties such as a high heat resistance, a high strength, and a surface activity, and is promisingly expected to have properties useful for various applications. Such a metal oxide fiber is produced commonly by a melt-fiberizing method. This melt-fiberizing method is as follows. A metal oxide raw material and a low-melting-point compound such as silica are mixed. Next, this mixture is melted in a high-temperature furnace, and then, the melt is taken out as a thin stream. High-pressure air is blown against the thin stream, or a centrifugal force is applied thereto, whereby the stream is rapidly cooled to form a metal oxide fiber. In the melt-fiberizing method, however, the metal oxide raw material at a higher concentration involves a higher melting temperature, thus making it difficult to obtain a fiber having a high concentration of metal oxide.

In a generally known method of producing a fiber having a high concentration of metal oxide, a spinning solution containing a metal oxide source and a thickener is used to produce a fibrous precursor, which is spun by heating. However, this method has a problem in that the thickener, when burned off in a baking process, generates pores and cracks, causing an insufficient strength.

The polymetalloxane-containing composition can be treated in the form of a solution, and thus, can be spun without undergoing a melting step. In addition, the composition is treated without a thickener, thus making it possible to obtain a dense metal oxide fiber. Thus, it is made possible to easily obtain a metal oxide fiber having characteristics such as a high heat resistance, a high strength, and a surface activity.

### Method of Producing Fiber

A method of producing a fiber according to an example includes at least a spinning step of spinning the above-mentioned polymetalloxane-containing composition to obtain a fiber. In this spinning step, a known method can be used as the method of spinning the composition. Examples of this spinning method include a dry spinning method, a wet spinning method, a dry-wet spinning method, and an electrospinning method.

The dry spinning method is a method in which the composition is packed into a container, the composition is brought under a load and thus extruded into an atmosphere through spinnerets having pores, and the organic solvent is evaporated to obtain a thread product. In this method, the composition may be heated after being packed in a container, and be decreased in viscosity when extruded. In addition, the composition may be extruded into a heated atmosphere with the evaporation rate of the organic solvent controlled. It is also possible that, after the composition is extruded, the thread product is stretched using a rotating roller or a high-speed air flow.

The wet spinning is a method in which the composition or the like is extruded into a coagulation bath through spinnerets having pores, and the organic solvent is removed to obtain a thread product. A coagulation bath to be preferably used is water or a polar solvent. In addition, the dry-wet spinning is a method in which the composition is extruded into an atmosphere, and then immersed in a coagulation bath, and the organic solvent is removed to obtain a thread product.

The electrospinning method is a method in which a high voltage is applied to a nozzle packed with the composition, and electric charges are thereby gathered in liquid droplets at the tip of the nozzle, and repel each other to spread the droplets, whereby the solution stream is stretched to be spun. This method makes it possible to obtain a thread product having a small diameter. Accordingly, using an electrospinning method makes it possible to obtain a thin thread product having a diameter of tens of nanometers to several micrometers.

Among these, in particular, a dry spinning method or an electrospinning method can be preferably used as a spinning method in the spinning step.

A fiber obtained in the spinning step may undergo, if desired, a drying treatment, a steam treatment, a hot-water treatment, or a combination of these treatments before undergoing baking.

Baking a fiber obtained in the above-mentioned spinning step makes it possible that the cross-linking reaction progresses, and in addition, organic components such as organic groups are removed, whereby a metal oxide fiber having an excellent strength is obtained. That is, when a metal oxide fiber is produced, a method of producing a fiber according to an example includes a step of spinning the composition as above-mentioned, and a baking step of baking a fiber obtained in the spinning step. In this baking step, the baking temperature is subject to no particular limitation, and is preferably 200° C. or more and 2000° C. or less, still more preferably 400° C. or more and 1500° C. or less. The baking method is limited to no particular limitation. Examples of baking methods include a method of baking in an air atmosphere, a method of baking in an inert atmosphere such as nitrogen or argon, a method of baking in vacuum and the like.

In the baking step, the resulting metal oxide fiber may be further baked in a reducing atmosphere such as hydrogen. In the baking step, a fiber or a metal oxide fiber, which is obtained by spinning, may be baked with tension applied thereto.

Such a method makes it possible to obtain a continuous and dense metal oxide fiber having an average fiber diameter of 0.01 μm or more and 1000 μm or less. The metal oxide fiber preferably has an average fiber diameter of 0.01 μm or more and 1000 μm or less, still more preferably 0.10 μm or more and 200 μm or less. The average fiber diameter within the range enables the metal oxide fiber to be crackless and homogeneous.

The average fiber diameter of the resulting metal oxide fiber is determined by the following method. For example, an adhesive tape is bonded to a piece of backing paper. To the resulting piece, a single fiber the fiber diameter of which is to be measured is bonded horizontally to obtain a single fiber test piece. The upper face of this single fiber test piece is observed under an electron microscope to measure the width of an image of the single fiber test piece. Three measurements are taken along the length direction, and the average of the measurement values is regarded as the fiber diameter. This operation is performed on 20 single fibers selected randomly. The fiber diameters obtained are averaged to afford an average fiber diameter.

A metal oxide fiber obtained by spinning a solution of a polymetalloxane and baking the resulting product can be utilized as a photocatalyst, a heat-insulating material, a heat-radiating material, or a composite material such as a fiber-reinforced plastic (FRP). As a photocatalyst, the metal oxide fiber can be used for a filter for purification of water or the air and the like. As a heat-insulating material or a heat-radiating material, the metal oxide fiber can be used for an electric furnace, a nuclear fuel rod sheath, an engine turbine of an aircraft, a heat exchanger or the like.

### EXAMPLES

Our compositions, cured bodies, members, components, fibers and methods will now be described more specifically by way of Examples, but this disclosure is not limited to these Examples.

### Infrared Spectroscopic Analysis

Analysis by Fourier transform infrared spectroscopy (FT-IR) was performed by the following method. First, using a Fourier transform infrared spectrometer (FT 720, manufactured by Shimadzu Corporation), two silicon wafers superposed one upon another were measured, and the measurement result was used as a baseline. Next, one drop of a metal compound or a solution thereof was dropped on a silicon wafer and sandwiched between the silicon wafer and another silicon wafer. The resulting object was used as a measurement sample. An absorbance of the compound or a solution thereof was calculated from the difference between the absorbance of the measurement sample and the absorbance of the baseline, and the absorption peak was read.

### Measurement of Weight-Average Molecular Weight

The weight-average molecular weight (Mw) of the polymetalloxane was determined by gel permeation chromatography (GPC) using the following method. Lithium chloride was dissolved in N-methyl-2-pyrrolidone to prepare a 0.02 mol/dm³ lithium chloride/N-methyl-2-pyrrolidone solution as an eluent. A polymetalloxane was dissolved at a concentration of 0.2 wt % in the eluent, and the solution thus obtained was used as a sample solution. The eluent was allowed to flow through a porous gel column (TSK gel α-M and α-3000, one each, manufactured by Tosoh Corporation) at a flow rate of 0.5 mL/min, and 0.2 mL of the sample solution was injected into the column. The eluate from the column was detected by a differential refractive index detector (Model RI-201, manufactured by Showa Denko K.K.), and the elution time was analyzed to determine the weight-average molecular weight (Mw) in terms of polystyrene.

### Materials used in Examples and Comparative Examples

### Synthesis Example 1 Synthesis of Zirconium Compound (M-1)

Into a three-necked flask having a capacity of 500 ml, 32.8 g (0.1 mol) of tetrapropoxyzirconium was fed, and the flask was immersed in an oil bath at 40° C. The resulting mixture was stirred for 30 minutes. Thereafter, using a dropping funnel, 9.0 g (0.1 mol) of trimethylsilanol was added over 1 hour, and after the addition, the mixture was stirred for additional 1 hour. The contents of the flask were transferred to a 200 ml recovery flask, and propanol thus formed was distilled off under reduced pressure to obtain a colorless liquid zirconium compound (M-1).

This zirconium compound (M-1) was analyzed by FT-IR using the above-mentioned method, resulting in verifying that an absorption peak of Zr—O—Si (968 cm⁻¹) existed, and that no absorption of silanol (883 cm⁻¹) existed, and thus, that the zirconium compound (M-1) obtained was tri-n-propoxy(trimethylsiloxy)zirconium.

### Synthesis Example 2 Synthesis of Aluminum Compound (M-2)

Into a three-necked flask having a capacity of 500 ml, 24.6 g (0.1 mol) of tri-s-butoxyaluminum was fed, and the flask was immersed in an oil bath at 40° C. The resulting mixture was stirred for 30 minutes. Thereafter, using a dropping funnel, 9.0 g (0.1 mol) of trimethylsilanol was added over 1 hour and, after the addition, the mixture was stirred for additional 1 hour. The contents of the flask were transferred to a 200 ml recovery flask, and isopropanol thus formed was distilled off under reduced pressure to obtain a colorless liquid aluminum compound (M-2).

This aluminum compound (M-2) was analyzed by FT-IR using the above-mentioned method, resulting in verifying that an absorption peak of Al—O—Si (949 cm⁻¹) existed, and that no absorption of silanol (883 cm⁻¹) existed, and thus, that the aluminum compound (M-2) obtained was di-s-butoxy(trimethylsiloxy)aluminum.

TABLE 1

| | | Raw Material 1 | Raw Material 2 | Metal Compound Obtained | Deduced Structure |
|---|---|---|---|---|---|
| Synthesis Example 1 | Zirconium Compound (M-1) | 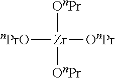 | 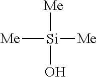 | Tri-n- propoxy (trimethylsiloxy)zirconium | 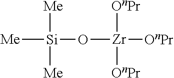 |
| Synthesis Example 2 | Aluminum Compound (M-2) | 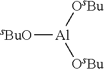 | 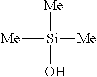 | Di-s- butoxy(trimethylsiloxy)aluminum | 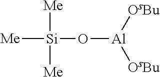 |

### (A) Polymetalloxane

### Synthesis Example 3 Polymetalloxane (A-1)

Tri-n-propoxy(trimethylsiloxy)zirconium in an amount of 14.30 g (0.04 mol), 15.74 g (0.06 mol) of di-s-butoxy(trimethylsiloxy)aluminum, and 30.00 g of N,N′-dimethylisobutylamide (hereinafter referred to as DMIB) as a solvent were mixed to obtain a solution 1. In addition, 4.32 g (0.24 mol) of water, 50.0 g of isopropyl alcohol (IPA) as a water-diluted solvent, and 1.85 g (0.01 mol) of tributylamine as a polymerization catalyst were mixed to obtain a solution 2.

Into a three-necked flask having a capacity of 500 ml, the entire amount of the solution 1 was fed, and the flask was immersed in an oil bath at 40° C. The solution was stirred for 30 minutes. Thereafter, the entire amount of the solution 2 was fed into a dropping funnel for the purpose of hydrolysis, and then added in the flask over 1 hour. During the addition of the solution 2, precipitation did not occur in the liquid in the flask, and the solution was uniformly colorless and transparent. After the addition of the solution 2, the mixture was stirred for additional 1 hour to obtain a hydroxyl group-containing metal compound. Thereafter, for the purpose of polycondensation, the oil bath was heated to 140° C. over 30 minutes. One hour after the temperature started rising, the internal temperature of the solution reached 100° C., whereafter the mixture was heated with stirring for 2 hours (the internal temperature was 100 to 130° C.). During the reaction, IPA, n-propanol, 2-butanol and water were distilled off. During the heating with stirring, precipitation did not occur in the liquid in the flask, and the solution was uniformly transparent.

After completion of the heating, the liquid in the flask was cooled to room temperature to obtain a polymetalloxane solution. The appearance of the polymetalloxane solution obtained was pale yellow transparent.

The solid concentration of the polymetalloxane solution obtained was determined, and then, DMIB was added in such a manner that the solid concentration became 30 wt % to obtain a polymetalloxane (A-1) solution.

Analyzing the polymetalloxane (A-1) solution by FT-IR using the above-mentioned method resulted in verifying that an absorption peak of Zr—O—Si (968 cm⁻¹) and an absorption peak of Al—O—Si (780 cm⁻¹) were observed, and thus that the polymetalloxane was that which had a trimethylsiloxy group. The weight-average molecular weight (Mw) of the polymetalloxane (A-1) was 500,000 in terms of polystyrene. sss

### Synthesis Example 4 Polymetalloxane (A-2)

Tri-n-propoxy(trimethylsiloxy)zirconium in an amount of 14.30 g (0.04 mol), 15.74 g (0.06 mol) of di-s-butoxy(trimethylsiloxy)aluminum, and 20.00 g of DMIB as a solvent were mixed to obtain a solution 1. In addition, 4.32 g (0.24 mol) of water and 50.0 g of IPA as a water-diluted solvent were mixed to obtain a solution 2. Furthermore, 3.99 g (0.01 mol) of 1,3,5-tris(4-aminophenoxy)benzene as a polymerization catalyst and 20.00 g of DMIB as a dilution solvent were mixed to obtain a solution 3.

Into a three-necked flask having a capacity of 500 ml, the entire amount of the solution 1 was fed, and the flask was immersed in an oil bath at 40° C. The solution was stirred for 30 minutes. Thereafter, the entire amount of the solution 2 was fed into a dropping funnel for the purpose of hydrolysis, and then added in the flask over 1 hour. During the addition of the solution 2, precipitation did not occur in the liquid in the flask, and the solution was uniformly colorless and transparent. After the addition of the solution 2, the mixture was stirred for additional 1 hour to obtain a hydroxyl group-containing metal compound. Thereafter, for the purpose of polycondensation, the solution 3 was added, and the oil bath was heated to 140° C. over 30 minutes. One hour after the temperature started rising, the internal temperature of the solution reached 100° C., and the mixture was heated with stirring for 2 hours (the internal temperature was 100 to 130° C.). During the reaction, IPA, n-propanol, 2-butanol and water were distilled off. During the heating with stirring, precipitation did not occur in the liquid in the flask, and the solution was uniformly transparent.

After completion of the heating, the liquid in the flask was cooled to room temperature to obtain a polymetalloxane solution. The appearance of the polymetalloxane solution obtained was pale yellow transparent.

The solid concentration of the polymetalloxane solution obtained was determined, and then, DMIB was added in such a manner that the solid concentration became 30 wt % to obtain a polymetalloxane (A-2) solution.

Analyzing the polymetalloxane (A-2) solution by FT-IR using the above-mentioned method resulted in verifying that an absorption peak of Zr—O—Si (968 cm⁻³) and an absorption peak of Al—O—Si (780 cm⁻¹) were observed, and thus that the polymetalloxane was that which had a trimethylsiloxy group. The weight-average molecular weight (Mw) of the polymetalloxane (A-2) was 770,000 in terms of polystyrene.

### Synthesis Example 5 Polymetalloxane (A-3)

Tri-n-propoxy(trimethylsiloxy)zirconium in an amount of 32.19 g (0.09 mol), 2.62 g (0.01 mol) of di-s-butoxy(trimethylsiloxy)aluminum, and 30.00 g of DMIB as a solvent were mixed to obtain a solution 1. In addition, 5.23 g (0.29 mol) of water, 50.0 g of IPA as a water-diluted solvent, and 1.85 g (0.01 mol) of tributylamine as a polymerization catalyst were mixed to obtain a solution 2.

Into a three-necked flask having a capacity of 500 ml, the entire amount of the solution 1 was fed, and the flask was immersed in an oil bath at 40° C. The solution was stirred for 30 minutes. Thereafter, the entire amount of the solution 2 was fed into a dropping funnel for the purpose of hydrolysis, and then added in the flask over 1 hour. During the addition of the solution 2, precipitation did not occur in the liquid in the flask, and the solution was uniformly colorless and transparent. After the addition of the solution 2, the mixture was stirred for additional 1 hour to obtain a hydroxyl group-containing metal compound. Thereafter, for the purpose of polycondensation, the oil bath was heated to 140° C. over 30 minutes. One hour after the temperature started rising, the internal temperature of the solution reached 100° C., and the mixture was heated with stirring for 2 hours (the internal temperature was 100 to 130° C.). During the reaction, IPA, n-propanol, 2-butanol and water were distilled off. During the heating with stirring, precipitation did not occur in the liquid in the flask, and the solution was uniformly transparent.

After completion of the heating, the liquid in the flask was cooled to room temperature to obtain a polymetalloxane solution. The appearance of the obtained polymetalloxane solution was pale yellow transparent.

The solid concentration of the polymetalloxane solution obtained was determined, and then, DMIB was added in such a manner that the solid concentration became 30 wt % to obtain a polymetalloxane (A-3) solution.

Analyzing the polymetalloxane (A-3) solution by FT-IR using the above-mentioned method resulted in verifying that an absorption peak of Zr—O—Si (968 cm⁻¹) and an absorption peak of Al—O—Si (780 cm⁻¹) were observed, and thus that the polymetalloxane was that which had a trimethylsiloxy group. The weight-average molecular weight (Mw) of the polymetalloxane (A-3) was 850,000 in terms of polystyrene.

### Synthesis Example 6 Polymetalloxane (A-4)

Tri-n-propoxy(trimethylsiloxy)zirconium in an amount of 35.77 g (0.10 mol) and 50.00 g of DMIB as a solvent were mixed to obtain a solution 1. In addition, 5.41 g (0.30 mol) of water, 50.0 g of IPA as a water-diluted solvent, and 1.85 g (0.01 mol) of tributylamine as a polymerization catalyst were mixed to obtain a solution 2.

Into a three-necked flask having a capacity of 500 ml, the entire amount of the solution 1 was fed, and the flask was immersed in an oil bath at 40° C. The solution was stirred for 30 minutes. Thereafter, the entire amount of the solution 2 was fed into a dropping funnel for the purpose of hydrolysis, and then added in the flask over 1 hour. During the addition of the solution 2, precipitation did not occur in the liquid in the flask, and the solution was uniformly colorless and transparent. After the addition of the solution 2, the mixture was stirred for additional 1 hour to obtain a hydroxyl group-containing metal compound. Thereafter, for the purpose of polycondensation, the oil bath was heated to 140° C. over 30 minutes. One hour after the temperature started rising, the internal temperature of the solution reached 100° C., and the mixture was heated with stirring for 2 hours (the internal temperature was 100 to 130° C.). During the reaction, IPA, n-propanol, 2-butanol and water were distilled off. During the heating with stirring, precipitation did not occur in the liquid in the flask, and the solution was uniformly transparent.

After completion of the heating, the liquid in the flask was cooled to room temperature to obtain a polymetalloxane solution. The appearance of the polymetalloxane solution obtained was pale yellow transparent.

The solid concentration of the polymetalloxane solution obtained was determined, and then, DMIB was added in such a manner that the solid concentration became 30 wt % to obtain a polymetalloxane (A-4) solution.

Analyzing the polymetalloxane (A-4) solution by FT-IR using the above-mentioned method resulted in verifying that an absorption peak of Zr—O—Si (968 cm⁻¹) was observed, and thus that the polymetalloxane was that which had a trimethylsiloxy group. The weight-average molecular weight (Mw) of the polymetalloxane (A-4) was 940,000 in terms of polystyrene.

### Synthesis Example 7 Polymetalloxane (A-5)

Di-s-butoxy(trimethylsiloxy)aluminum in an amount of 26.24 g (0.10 mol) and 30.00 g of DMIB as a solvent were mixed to obtain a solution 1. In addition, 3.60 g (0.20 mol) of water, 50.0 g of IPA as a water-diluted solvent, and 1.85 g (0.01 mol) of tributylamine as a polymerization catalyst were mixed to obtain a solution 2.

Into a three-necked flask having a capacity of 500 ml, the entire amount of the solution 1 was fed, and the flask was immersed in an oil bath at 40° C. The solution was stirred for 30 minutes. Thereafter, the entire amount of the solution 2 was fed into a dropping funnel for the purpose of hydrolysis, and then added in the flask over 1 hour. During the addition of the solution 2, precipitation did not occur in the liquid in the flask, and the solution was uniformly colorless and transparent. After the addition, the mixture was stirred for additional 1 hour to obtain a hydroxyl group-containing metal compound. Thereafter, for the purpose of polycondensation, the oil bath was heated to 140° C. over 30 minutes. One hour after the temperature started rising, the internal temperature of the solution reached 100° C., and the mixture was heated with stirring for 2 hours (the internal temperature was 100 to 130° C.). During the reaction, IPA, n-propanol, 2-butanol and water were distilled off. During heating with stirring, precipitation did not occur in the liquid in the flask, and the solution was uniformly transparent.

After completion of the heating, the liquid in the flask was cooled to room temperature to obtain a polymetalloxane solution. The appearance of the polymetalloxane solution obtained was pale yellow transparent.

The solid concentration of the polymetalloxane solution obtained was determined, and then, DMIB was added in such a manner that the solid concentration became 30 wt % to obtain a polymetalloxane (A-5) solution.

Analyzing the polymetalloxane (A-5) solution by FT-IR using the above-mentioned method resulted in verifying that an absorption peak of Al—O—Si (780 cm⁻¹) was observed, and thus that the polymetalloxane was that which had a trimethylsiloxy group. The weight-average molecular weight (Mw) of the polymetalloxane (A-5) was 240,000 in terms of polystyrene.

TABLE 2

| | | Solution 1 | | | | | |
|---|---|---|---|---|---|---|---|
| | | Metal Alkoxide 1 | | Metal Alkoxide 2 | | | |
| | | | Amount | | Amount | | Solution 2 |
| | | Kind | Added | Kind | Added | Solvent | Water |
| Synthesis | Polymetalloxane | Tri-n-propoxy | 14.30 g | Di-s-butoxy | 15.74 g | DMIB | 4.32 g |
| Example 3 | (A-1) Solution | (trimethylsiloxy) | (0.04 mol) | (trimethylsiloxy) | (0.06 mol) | 30.00 g | (0.24 mol) |
| | | zirconium | | aluminum | | | |
| Synthesis | Polymetalloxane | Tri-n-propoxy | 14.30 g | Di-s-butoxy | 15.74 g | DMIB | 4.32 g |
| Example 4 | (A-2) Solution | (trimethylsiloxy) | (0.04 mol) | (trimethylsiloxy) | (0.06 mol) | 20.00 g | (0.24 mol) |
| | | zirconium | | aluminum | | | |
| Synthesis | Polymetalloxane | Tri-n-propoxy | 32.19 g | Di-s-butoxy | 2.62 g | DMIB | 5.23 g |
| Example 5 | (A-3) Solution | (trimethylsiloxy) | (0.09 mol) | (trimethylsiloxy) | (0.01 mol) | 50.00 g | (0.29 mol) |
| | | zirconium | | aluminum | | | |
| Synthesis | Polymetalloxane | Tri-n-propoxy | 35.77 g | — | — | DMIB | 5.41 g |
| Example 6 | (A-4) Solution | (trimethylsiloxy) | (0.10 mol) | | | 50.00 g | (0.30 mol) |
| | | zirconium | | | | | |
| Synthesis | Polymetalloxane | — | — | Di-s-butoxy | 26.24 g | DMIB | 3.60 g |
| Example 7 | (A-5) Solution | | | (trimethylsiloxy) | (0.10 mol) | 30.00 g | (0.20 mol) |
| | | | | aluminum | | | |

| | | | | | | Weight- |
|---|---|---|---|---|---|---|
| | | Solution 2 | | | | average |
| | | Water- | | Solution 3 | | Molecular |
| | | diluted | Polymerization | Dilution | Polymerization | Weight |
| | | Solvent | Catalyst | Solvent | Catalyst | (Mw) |
| Synthesis | Polymetalloxane | IPA 50 g | Tributylamine | — | — | 500,000 |
| Example 3 | (A-1) Solution | | 1.85 g | | | |
| | | | (0.01 mol) | | | |
| Synthesis | Polymetalloxane | IPA 50 g | — | DMIB | 1,3,5-Tris | 770,000 |
| Example 4 | (A-2) Solution | | | 10.00 g | (4-aminophenoxy) | |
| | | | | | benzene | |
| | | | | | 3.99 g | |
| | | | | | (0.01 mol) | |
| Synthesis | Polymetalloxane | IPA 50 g | Tributylamine | — | — | 850,000 |
| Example 5 | (A-3) Solution | | 1.85 g | | | |
| | | | (0.01 mol) | | | |
| Synthesis | Polymetalloxane | IPA 50 g | Tributylamine | — | — | 940,000 |
| Example 6 | (A-4) Solution | | 1.85 g | | | |
| | | | (0.01 mol) | | | |
| Synthesis | Polymetalloxane | IPA 50 g | Tributylamine | — | — | 240,000 |
| Example 7 | (A-5) Solution | | 1.85 g | | | |
| | | | (0.01 mol) | | | |

### (B) Aromatic Polyfunctional Amine Compound

(B-1) TAPOB: 1,3,5-Tris(4-aminophenoxy)benzene (manufactured by Seika Corporation)
(B-2) 3,4′-DAE: 3,4′-Diaminophenyl ether (Fujifilm Wako Pure Chemical Corporation).
(B-3) 1,3,5-Tris(4-aminophenyl)triazine (Fujifilm Wako Pure Chemical Corporation)
(B-4) [1,1′-Biphenyl]-4,4′ diamine,N′,N′,N′,N′-tetrakis(4-aminophenyl) (Fujifilm Wako Pure Chemical Corporation)
(B′-5) Aniline (Fujifilm Wako Pure Chemical Corporation)
(B′-6) Tris(2-aminoethyl)amine (Tokyo Chemical Industry Co., Ltd.) Solvent
DMIB: N,N′-dimethylisobutylamide (Mitsubishi Gas Chemical Company, Inc.)

### Example 1

First, 5.0 g (B-1) the aromatic polyfunctional amine compound and 28.3 g of DMIB were added to 66.7 g of a 30 wt % polymetalloxane (A-1) solution obtained as above-mentioned, and the resulting mixture was stirred to obtain a composition 1.

Three 4-inch silicon wafers were each spin-coated with the composition 1 using a spin coater (“1H-360S (tradename)”, manufactured by Mikasa Co., Ltd.) to produce coating films having different thicknesses. The resulting silicon wafers were heated at 100° C. for 5 minutes using a hot plate (“SCW-636 (tradename)”, manufactured by Dainippon Screen Mfg. Co., Ltd.) to form prebaked films, which were subsequently cured at 300° C. for 5 minutes using the hot plate to produce cured films. Then, the cured films were baked at 700° C. under a nitrogen atmosphere for 30 minutes using a tube furnace to produce cured films having a film thickness of 0.5 μm, 1.0 μm, and 1.2 μm respectively. The film thickness was measured using an optical interferometric film-thickness meter (Lambda Ace STM602, manufactured by Dainippon Screen Mfg. Co., Ltd.).

### Measurement of Density of Cured Product and Atomic Ratio

The density of the cured product and the ratio of the carbon atom to the total amount of substance of the metal atom were determined using a Pelletron 3SDH (manufactured by National Electrodtstics), in which irradiating the cured product with an ion beam was followed by analyzing the scattered ion energy. In this regard, the measurement conditions were as follows: incident ions, 4He++; incident energy, 2300 keV; incidence angle, 0 degree; scattering angle, 160 degree; electric current for sample, 5 nA; beam diameter, 2 mm φ; and amount of irradiation, 65 μC.

### Evaluation of Crack Resistance of Cured Product

The crack resistance of the cured product obtained was rated in the following 5 steps. Rating 4 or higher was regarded as acceptable.
5: No crack is observed under an optical microscope (magnification: 5 times)
4: Cracks are slightly observed under an optical microscope (magnification: 5 times)
3: Cracks are clearly observed under an optical microscope (magnification: 5 times)
2: Cracks are slightly observed by normal visual observation
1: Cracks are clearly observed by normal visual observation.
The results of evaluation of the refractive index and crack resistance are tabulated in Table 3.

### Examples 2 to 13 and Comparative Examples 1 to 3

In the same manner as in Example 1, the compositions having the components listed in Tables 3 and 4 were obtained. The compositions were each evaluated in the same manner as in Example 1. The evaluation results are Tabulated in Tables 3 and 4.

### Example 14

The composition 1 obtained in Example 1 was concentrated under reduced pressure so as to have a solid concentration of 60%. The composition 1 concentrated had a viscosity of 2000 P.

Subsequently, a 10 mL syringe (manufactured by Musashi Engineering, Inc.) for a dispenser was filled with a solution of the composition 1 concentrated. To this syringe, a plastic needle (having an inner diameter of 0.20 mm, manufactured by Musashi Engineering, Inc.) for a dispenser was attached as a mouth piece, and an adapter tube (manufactured by Musashi Engineering, Inc.) was attached. The adapter tube and a compressed air line were connected. The filling was extruded into an air atmosphere at a pressure of 0.4 MPa and at 25° C. to obtain a thread product.

The average fiber diameter of the thread products obtained was measured by the following method. First, an adhesive tape (a double-sided carbon adhesive tape (with an aluminum base material) for SEM, manufactured by Nisshin-EM Co., Ltd.) was bonded to a piece of backing paper. To the resulting piece, a thread product or a metal oxide fiber, the fiber diameter of which was to be measured, was bonded horizontally to obtain a single fiber test piece. The upper face of this single fiber test piece was observed under an electron microscope to measure the width of an image of the single fiber test piece. Three measurements were taken along the length direction, and the average of the measurement values was regarded as the fiber diameter. This operation was performed on 20 thread products or metal oxide fibers selected randomly. The fiber diameters obtained were averaged to afford an average fiber diameter. The average fiber diameter of the thread products obtained was 60 μm.

In addition, the thread product obtained was dried at 25° C. for 24 hours, and then, baked under an air atmosphere at a heating rate of 10° C./minute and at 1100° C. for 60 minutes using an electric muffle furnace (FUW263PA, manufactured by ADVANTEC Co., Ltd.) to obtain a fiber. The average fiber diameter of the fiber baked was measured by the same method as that of the above-mentioned thread product. As a result, the average fiber diameter of the fiber baked was 30 μm.

In Example 14, the qualitative analysis of the fiber baked was performed by the following wide-angle X-ray diffraction method (hereinafter referred to as XRD for short). Specifically, an X-ray diffractometer (D8 ADVANCE, manufactured by Bruker AXS GmbH) was used to obtain a diffraction pattern in the measurement range (2θ) of from 10 to 80°. Then, the measurement result was compared to the standard data so that the fiber was identified. As a result, the fiber baked was found to be zirconium oxide in cubical crystal form. This verified that the fiber baked was a metal oxide fiber.

In addition, the tensile strength of the fiber baked was measured by the following method. Specifically, a TENSILON universal tensile testing machine (RTM-100, manufactured by Orientec Corporation) was used to pull the fiber as an object of measurement at a measurement length of 25 mm and at a tension rate of 1 mm/minute. The strength at which the fiber was broken was regarded as the tensile strength. In this regard, the measurement value of the tensile strength was the average of the tensile strength values of 20 fibers selected randomly. In Example 14, the tensile strength of the fiber baked was 1.4 GPa.

TABLE 3

| | | | Example 1 | Example 2 | Example 3 | Example 4 |
|---|---|---|---|---|---|---|
| Composition | (A) Polymetalloxane | Kind | A-1 | A-1 | A-1 | A-1 |
| | 30 wt % Solution | Amount [g] | 66.7 | 70.0 | 68.9 | 58.3 |
| | | Weight-average | 500,000 | 500,000 | 500,000 | 500,000 |
| | | Molecular Weight (Mw) | | | | |
| | (B) Aromatic | Kind | B-1 | B-1 | B-1 | B-1 |
| | Polyfunctional | Amount [g] | 5.0 | 4.0 | 4.3 | 7.5 |
| | Amine Compound | Number of General | 3 | 3 | 3 | 3 |
| | | Formulae (1) | | | | |
| | Solvent [g] | | DMIB | DMIB | DMIB | DMIB |
| | | | 28.3 | 26.0 | 26.8 | 34.2 |
| | Amount of (B) Aromatic Polyfunctional Amine | | 25 | 19 | 21 | 43 |
| | Compound with respect to 100 parts by mass of | | | | | |
| | (A) Polymetalloxane | | | | | |
| | [parts by mass] | | | | | |
| | Solid Concentration [%] | | 25% | 25% | 25% | 25% |
| Evaluation | Ratio of Carbon Atom to Total Amount of | | 2.99 | 2.25 | 2.50 | 5.17 |
| Results | Substance of Metal Atom | | | | | |
| | Film Density [g/cm³] | | 2.45 | 2.68 | 2.61 | 2.30 |
| | Crack Resistance | Film Thickness 0.5 μm | 5 | 5 | 5 | 5 |
| | | Film Thickness 1.0 μm | 5 | 5 | 5 | 5 |
| | | Film Thickness 1.2 μm | 5 | 4 | 5 | 5 |
| | | | Example 5 | Example 6 | Example 7 | Example 8 |
| Composition | (A) Polymetalloxane | Kind | A-1 | A-1 | A-1 | A-1 |
| | 30 wt % Solution | Amount [g] | 41.7 | 31.7 | 66.7 | 66.7 |
| | | Weight-average | 500,000 | 500,000 | 500,000 | 500,000 |
| | | Molecular Weight (Mw) | | | | |
| | (B) Aromatic | Kind | B-1 | B-1 | B-2 | B-3 |
| | Polyfunctional | Amount [g] | 12.5 | 15.5 | 5.0 | 5.0 |
| | Amine Compound | Number of General | 3 | 3 | 2 | 3 |
| | | Formulae (1) | | | | |
| | Solvent [g] | | DMIB | DMIB | DMIB | DMIB |
| | | | 45.8 | 52.8 | 28.3 | 28.3 |
| | Amount of (B) Aromatic Polyfunctional Amine | | 100 | 163 | 25 | 25 |
| | Compound with respect to 100 parts by mass of | | | | | |
| | (A) Polymetalloxane | | | | | |
| | [parts by mass] | | | | | |
| | Solid Concentration [%] | | 25% | 25% | 25% | 25% |
| Evaluation | Ratio of Carbon Atom to Total Amount of | | 11.91 | 19.50 | 2.85 | 3.11 |
| Results | Substance of Metal Atom | | | | | |
| | Film Density [g/cm³] | | 2.04 | 1.80 | 2.48 | 2.52 |
| | Crack Resistance | Film Thickness 0.5 μm | 5 | 5 | 5 | 5 |
| | | Film Thickness 1.0 μm | 5 | 4 | 4 | 5 |
| | | Film Thickness 1.2 μm | 5 | 4 | 3 | 5 |

TABLE 4

| | | | Example 9 | Example 10 | Example 11 | Example 12 |
|---|---|---|---|---|---|---|
| Composition | (A) Polymetalloxane | Kind | A-1 | A-2 | A-3 | A-4 |
| | 30 wt % Solution | Amount [g] | 66.7 | 66.7 | 66.7 | 66.7 |
| | | Weight-average | 500,000 | 770,000 | 850,000 | 940,000 |
| | | Molecular Weight (Mw) | | | | |
| | (B) Aromatic | Kind | B-4 | B-1 | B-1 | B-1 |
| | Polyfunctional Amine | Amount [g] | 5.0 | 5.0 | 5.0 | 5.0 |
| | Compound | Number of General | 4 | 3 | 3 | 3 |
| | | Formulae (1) | | | | |
| | Solvent [g] | | DMIB | DMIB | DMIB | DMIB |
| | | | 28.3 | 28.3 | 28.3 | 28.3 |
| | Amount of (B) Aromatic Polyfunctional Amine | | 25 | 25 | 25 | 25 |
| | Compound with respect to 100 parts by mass of (A) | | | | | |
| | Polymetalloxane | | | | | |
| | [parts by mass] | | | | | |
| | Solid Concentration [%] | | 25% | 25% | 25% | 25% |
| Evaluation | Ratio of Carbon Atom to Total Amount of | | 3.23 | 2.89 | 2.92 | 3.04 |
| Results | Substance of Metal Atom | | | | | |
| | Film Density [g/cm3] | | 2.60 | 2.62 | 2.91 | 2.98 |
| | Crack Resistance | Film Thickness 0.5 μm | 5 | 5 | 5 | 5 |
| | | Film Thickness 1.0 μm | 5 | 5 | 5 | 5 |
| | | Film Thickness 1.2 μm | 5 | 5 | 5 | 5 |
| | | | | Comparative | Comparative | Comparative |
| | | | Example 13 | Example 1 | Example 2 | Example 3 |
| Composition | (A) Polymetalloxane | Kind | A-5 | A-1 | A-1 | A-1 |
| | 30 wt % Solution | Amount [g] | 66.7 | 83.3 | 66.7 | 66.7 |
| | | Weight-average | 240,000 | 500,000 | 500,000 | 500,000 |
| | | Molecular Weight (Mw) | | | | |
| | (B) Aromatic | Kind | B-1 | — | B′ -5 | B′ -6 |
| | Polyfunctional Amine | Amount [g] | 5.0 | | 5.0 | 5.0 |
| | Compound | Number of General | 3 | | 1 | 3 |
| | | Formulae (1) | | | | |
| | Solvent [g] | | DMIB | DMIB | DMIB | DMIB |
| | | | 28.3 | 16.7 | 28.3 | 28.3 |
| | Amount of (B) Aromatic Polyfunctional Amine | | 25 | 0 | 25 | 25 |
| | Compound with respect to 100 parts by mass of (A) | | | | | |
| | Polymetalloxane | | | | | |
| | [parts by mass] | | | | | |
| | Solid Concentration [%] | | 25% | 25% | 25% | 25% |
| Evaluation | Ratio of Carbon Atom to Total Amount of | | 2.93 | 0.00 | 2.43 | 1.58 |
| Results | Substance of Metal Atom | | | | | |
| | Film Density [g/cm3] | | 2.01 | 2.98 | 2.42 | 2.11 |
| | Crack Resistance | Film Thickness 0.5 μm | 5 | 1 | 2 | 1 |
| | | Film Thickness 1.0 μm | 5 | 1 | 1 | 1 |
| | | Film Thickness 1.2 μm | 5 | 1 | 1 | 1 |

1-17. (canceled)

18. A composition comprising: (A) a polymetalloxane having a repeating structure of a metal atom selected from the group consisting of Al, Sc, Ti, V, Cr, Mn, Fe, Co, Ni, Cu, Zn, Ga, Ge, Y, Zr, Nb, Mo, In, Sn, Sb, Hf, Ta, W, and Bi and an oxygen atom; and (B) an aromatic polyfunctional amine compound.

19. The composition according to claim 18, wherein (B) the aromatic polyfunctional amine compound has, in one molecule, 2 to 30 structures represented by general formula (1): 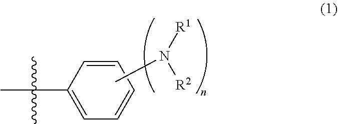
wherein, in general formula (1), R¹ and R² independently represent a hydrogen atom or a C₁₋₈ organic group; and n is an integer of 1 to 3.

20. The composition according to claim 18, wherein an amount of (B) the aromatic polyfunctional amine compound is 20 to 150 parts by mass with respect to 100 parts by mass of (A) the polymetalloxane.

21. The composition according to claim 18, wherein (A) the polymetalloxane has a weight-average molecular weight of 10,000 or more and 2,000,000 or less.

22. The composition according to claim 18, wherein (A) the polymetalloxane has a structural unit represented by general formula (2): 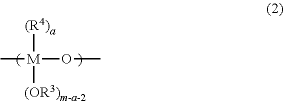
wherein R³ is a hydrogen atom or a C₁₋₁₂ alkyl group;
R⁴ is a hydroxy group, a C₁₋₁₂ alkyl group, a C₅₋₁₂ alicyclic alkyl group, a C₁₋₁₂ alkoxy group, a C₆₋₁₂ aryl group, a C₆₋₃₀ phenoxy group, a C₁₀₋₃₀ naphthoxy group, a C₇₋₁₃ aralkyl group, an (R⁵₃—SiO—) group, an (R⁶R⁷NO—) group, or a group having a metalloxane bond; a plurality of R³s and R⁴s existing in the polymetalloxane may be the same or different;
R⁵ is a group selected from the group consisting of a hydroxy group, a C₁₋₁₂ alkyl group, a C₅₋₁₂ alicyclic alkyl group, a C₁₋₁₂ alkoxy group, a C₆₋₁₂ aryl group, a C₇₋₁₃ aralkyl group, and a group having a siloxane bond; a plurality of R⁵s may be the same or different;
R⁶ and R⁷ are independently a hydrogen atom, C₁₋₁₂ alkyl group, a C₅₋₁₂ alicyclic alkyl group, a C₆₋₁₂ aryl group, or a C₇₋₁₃ aralkyl group; R⁶ and R⁷ may be linked via a carbon-carbon saturated bond or a carbon-carbon unsaturated bond to form a ring structure;
M represents a metal atom selected from the group consisting of Al, Sc, Ti, V, Cr, Mn, Fe, Co, Ni, Cu, Zn, Ga, Ge, Y, Zr, Nb, Mo, In, Sn, Sb, Hf, Ta, W, and Bi; and
m is an integer that represents a valence of a metal atom M, and a is an integer of 1 to (m-2).

23. The composition according to claim 18, wherein (A) the polymetalloxane has a repeating structure of a metal atom selected from the group consisting of Al, Ti, Y, Zr, Nb, and Sn and an oxygen atom.

24. A cured product formed by curing the composition according to claim 18.

25. A cured product comprising: a metal atom selected from the group consisting of Al, Sc, Ti, V, Cr, Mn, Fe, Co, Ni, Cu, Zn, Ga, Ge, Y, Zr, Nb, Mo, In, Sn, Sb, Hf, Ta, W, and Bi; an oxygen atom; a carbon atom; and a nitrogen atom; wherein the cured product contains an aromatic polyfunctional amine compound having, in one molecule, 2 to 30 structures represented by general formula (1): 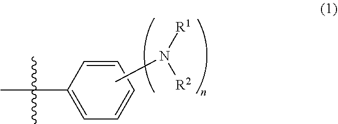
wherein, in general formula (1), R¹ and R² independently represent a hydrogen atom or a C₁₋₈ organic group; and n is an integer of 1 to 3; and wherein a ratio of the carbon atom to a total amount of substance of the metal atom is 1.0 to 25.0 in a heated product formed by heating the cured product at 700° C. under a nitrogen atmosphere for 1 hour.

26. A method of producing a cured product, comprising a baking step of heating the composition according to claim 18 to obtain a cured product.

27. A method of producing an inorganic solid pattern, comprising:
coating an inorganic solid with the composition according to claim 18;
heating a coating film from the coating step at a temperature of 100° C. or more and 1000° C. or less to obtain a cured film;
patterning the cured film to form a cured film pattern; and
patterning the inorganic solid by etching using the cured film pattern as a mask.

28. A method of producing an inorganic solid pattern according to claim 27, wherein the inorganic solid comprises one or more materials selected from the group consisting of SiO₂, Si₃N₄, Al₂O₃, TiO₂, and ZrO₂

29. The method of producing an inorganic solid pattern according to claim 27, wherein the inorganic solid is a laminate of a plurality of inorganic solid layers.

30. A member comprising the cured product according to claim 24.

31. An electronic component comprising the member according to claim 30.

32. A fiber composed of the composition according to claim 18.

33. A method of producing a fiber, comprising a step of spinning the composition according to claim 18.

34. A method of producing a metal oxide fiber, comprising: a step of spinning the composition according to claim 18; and a baking step of baking a fiber obtained in the spinning step.
